(19) United States
(12) Patent Application Publication
(10) Pub. No.: US 2022/0306901 A1
(43) Pub. Date: Sep. 29, 2022

(54) POLISHING COMPOSITION, POLISHING METHOD AND METHOD FOR PRODUCING SEMICONDUCTOR SUBSTRATE

(71) Applicant: FUJIMI INCORPORATED, Aichi (JP)

(72) Inventor: Ryota Mae, Aichi (JP)

(21) Appl. No.: 17/700,844

(22) Filed: Mar. 22, 2022

(30) Foreign Application Priority Data
Mar. 24, 2021 (JP) 2021-049533

(51) Int. Cl. C09G 1/02; H01L 21/304

(52) U.S. Cl. CPC C09G 1/02; H01L 21/304

(57) ABSTRACT

Provided is a polishing composition which is capable of polishing a polycrystalline silicon film and a silicon oxide film at high polishing speeds, and has a high selection ratio of the polishing speed of a polycrystalline silicon film.

The polishing composition contains abrasive grains, an alkaline compound, and a dispersing medium, wherein the abrasive grains contain silica particles having a silanol group density of higher than 0 group/nm² and 4 groups/nm² or less, electrical conductivity is 0.5 mS/cm or more and 10 mS/cm or less, and pH is 10 or more and 12 or less.

### CROSS-REFERENCE TO RELATED APPLICATION

The present application is based on Japanese Patent Application No. 2021-049533 filed on Mar. 24, 2021 and the disclosed content thereof is incorporated herein by reference in their entirety.

### BACKGROUND

### 1. Technical Field

The present invention relates to a polishing composition, a polishing method and a method for producing a semiconductor substrate.

### 2. Description of Related Arts

In recent years, new microprocessing technology has been developed with increased packing density and higher performance of LSI (Large Scale Integration). A chemical mechanical polishing (CMP) technique is one of such techniques, which is a technology often employed for flattening interlayer insulating films, forming metal plugs, and damascene wiring in LSI production steps, particularly a multilayer wiring step.

The CMP has been applied to each step in semiconductor production. An embodiment thereof is, for example, the application thereof to a gate forming step in transistor production. Transistor production may involve polishing materials such as metal, silicon, silicon oxide, polycrystalline silicon, and silicon nitride film, and thus high-speed polishing of each material is required in order to improve productivity. To meet such a need, for example, JP 2013-041992 A discloses a technology for improving the speed of polishing polycrystalline silicon.

### SUMMARY

The inventor of the present invention has studied to apply CMP to each step of semiconductor production, and thus have found that high-speed polishing of not only a polycrystalline silicon film, but also a silicon oxide film may be preferred in production, and that in such a case, a higher ratio of the polishing speed of a polycrystalline silicon film to the polishing speed of a silicon oxide film (hereinafter, may also be referred to as “the selection ratio of the polishing speed of a polycrystalline silicon film”) may be more preferred in production. However, such a new finding has almost never been studied.

Hence, a problem to be solved by the present invention is to provide a polishing composition, which is capable of polishing a polycrystalline silicon film and a silicon oxide film at high polishing speeds, and has a high selection ratio of the polishing speed of a polycrystalline silicon film.

### Solution to Problem

The inventor of the present invention has intensively studied to solve the above problems. As a result, the inventor has discovered that the problem is solved by a polishing composition containing abrasive grains, an alkaline compound, and a dispersing medium, wherein the abrasive grains contain silica particles having a silanol group density of higher than 0 group/nm² and 4 groups/nm² or less, electrical conductivity is 0.5 mS/cm or more and 10 mS/cm or less, and pH is 10 or more and 12 or less, and thus have completed the present invention.

### DETAILED DESCRIPTION

Embodiments of the present invention will be described below, but the present invention is not limited to only the following embodiments. In addition, unless otherwise specified, operation and measurement of physical properties and the like are performed under conditions of room temperature (20° C. to 25° C.)/relative humidity (40% RH to 50% RH). Further, as used herein, the term “X to Y” representing a numerical range refers to “X or more and Y or less”.

### <Polishing Composition>

The present invention is a polishing composition that is used for polishing an object to be polished, specifically, a polishing composition containing abrasive grains, an alkaline compound, and a dispersing medium, wherein the abrasive grains contain silica particles having a silanol group density of higher than 0 group/nm² and 4 groups/nm² or less, electrical conductivity is 0.5 mS/cm or more and 10 mS/cm or less, and pH is 10 or more and 12 or less. The polishing composition of the present invention having such a configuration is capable of polishing a polycrystalline silicon film and a silicon oxide film at high polishing speeds, and has a high selection ratio of the polishing speed of a polycrystalline silicon film (the ratio of the polishing speed of a polycrystalline silicon film to the polishing speed of a silicon oxide film).

According to the present invention, a polishing composition, which is capable of polishing a polycrystalline silicon film and a silicon oxide film at high polishing speeds, and has a high selection ratio of the polishing speed of a polycrystalline silicon film, is provided.

The reason why the polishing composition of the present invention exhibits the above effect is not necessarily clear, but can be considered as follows. However, the following mechanism is merely a presumption, and it goes without saying that the mechanism does not limit the technical scope of the present invention.

A polishing composition is generally used for polishing an object to be polished by physical action, which is a frictional action of rubbing the surface of a substrate with the composition, and chemical action of components other than abrasive grains on the surface of a substrate, as well as a combination thereof. Therefore, the form or the type of abrasive grains will have a major impact on the polishing speed.

The polishing composition of the present invention contains, as abrasive grains, silica particles having a silanol group density of higher than 0 group/nm² and 4 groups/nm² or less (hereinafter, may also be referred to as “silica particles having a low silanol group density”). Polycrystalline silicon has high hydrophobicity, and, in general, the lower the silanol group density of abrasive grains is, the higher the hydrophobicity is. Hence, such abrasive grains can more easily approach a hydrophobic object to be polished. Accordingly, upon polishing, silica particles having a low silanol group density contained in the polishing composition can approach an object to be polished, a polycrystalline silicon film, sufficiently apply the mechanical force on the surface (surface to be polished) of the polycrystalline silicon film, and thus can polish the surface appropriately.

Further, the polishing composition of the present invention has electrical conductivity of 0.5 mS/cm or more and 10 mS/cm or less, and a pH of 10 or more and 12 or less. Generally, making it alkaline results in increased speed of polishing a silicon oxide film, however, the selection ratio of the polishing speed of a polycrystalline silicon film tends to decrease because of this. In the present invention, the selection ratio of the polishing speed of a polycrystalline silicon film is also required to be high, requiring a balance between the polishing speed of a polycrystalline silicon film and the polishing speed of a silicon oxide film. In the present invention, when the polishing composition has electrical conductivity of 0.5 mS/cm or more and 10 mS/cm or less, it is considered that the thus compressed electric double layer suppresses electrostatic repulsion between abrasive grains and a silicon oxide film (for example, TEOS film), making the two to easily come close to each other and facilitating polishing. When the polishing composition has pH of 10 or more and 12 or less, the surface of a polycrystalline silicon film can be etched to become brittle. Hence, the polycrystalline silicon film can be easily polished. As described above, it can be said that the present invention is the result of finding a novel polishing composition, whereby a silicon oxide film can be efficiently polished because of the electrical conductivity and pH within specific ranges, and wherein silica particles having a low silanol group density approach the polycrystalline silicon film so as to contribute to polishing of the polycrystalline silicon film.

[Object to be Polished]

An object to be polished according to the present invention contains a polycrystalline silicon (polysilicon) film and a silicon oxide film. Specifically, the polishing composition according to the present invention is used for polishing an object to be polished containing a polycrystalline silicon film and a silicon oxide film.

Examples of a silicon oxide film include a TEOS-type silicon oxide surface (hereinafter, also simply referred to as “TEOS”) produced by using tetraethyl orthosilicate as a precursor, an HDP (High Density Plasma) film, an USG (Undoped Silicate Glass) film, a PSG (Phosphorus Silicate Glass) film, a BPSG (Boron-Phospho Silicate Glass) film, and an RTO (Rapid Thermal Oxidation) film.

Examples of an object to be polished according to the present invention may include other materials, in addition to a polycrystalline silicon (polysilicon) film and a silicon oxide film. Examples of other materials include silicon nitride (SiN), silicon carbon-nitride (SiCN), non-crystalline silicon (amorphous silicon), metal and SiGe.

Examples of the above metal include tungsten, copper, aluminum, cobalt, hafnium, nickel, gold, silver, platinum, palladium, rhodium, ruthenium, iridium, and osmium.

[Abrasive Grains]

The polishing composition of the present invention contains abrasive grains. In the polishing composition of the present invention, abrasive grains contain silica particles having a silanol group density of higher than 0 group/nm² and 4 groups/nm² or less. In an embodiment, abrasive grains are composed of silica particles having a silanol group density of higher than 0 group/nm² and 4 groups/nm² or less. The term “silanol group density” used herein refers to the number of silanol groups per unit area of the surface of silica particles. The silanol group density is an indicator representing the electric characteristics or chemical characteristics of the surface of silica particles.

The silanol group density used herein is found via calculation based on the specific surface area measured by a BET method and the amount of silanol groups measured by titration. For example, the average silanol group density (unit: group/nm²) of the surface of silica (polishing abrasive grains) can be calculated by a Sears titration method using neutralization titration described in G. W. Sears's “Analytical Chemistry, vol. 28, No. 12, 1956, 1982 to 1983”. The “Sears titration method” is an analytical technique that is generally employed by colloidal silica manufacturers to evaluate silanol group density, which involves calculating based on the amount of a sodium hydroxide aqueous solution required for changing the pH from 4 to 9. Measurement of silanol group density will be described in detail in the following examples.

In an embodiment of the present invention, selection or the like of a method for producing abrasive grains is effective to set the number of silanol groups per unit surface area of abrasive grains to be higher than 0 group/nm² and 4 groups/nm² or less. For example, heat treatment such as sintering is suitably performed. In an embodiment of the present invention, sintering is performed by, for example, maintaining abrasive grains (e.g., silica) under an environment at 120° C. to 200° C. for 30 minutes or longer. Through such heat treatment, the number of silanol groups on the surface of abrasive grains can be controlled to be a desired numerical value, such as a value of higher than 0 group/nm² and 4 groups/nm² or less. Therefore, in the present invention, such special treatment is performed for abrasive grains, so that the number of silanol groups on the surface of abrasive grains can be set to be higher than 0 group/nm² and 4 groups/nm² or less.

Silica particles have a silanol group density of, in an embodiment, higher than 0 group/nm² and 4 groups/nm² or less. Further, silica particles have a silanol group density of preferably 0.5 group/nm² or more and 4 groups/nm² or less, more preferably 0.6 group/nm² or more and 3.8 groups/nm² or less, further preferably 0.8 group/nm² or more and 3.6 groups/nm² or less, particularly preferably 0.9 group/nm² or more and 3.5 groups/nm² or less, and most preferably 1 group/nm² or more and 3 groups/nm² or less. Silica particles having a silanol group density within the above ranges allow, upon polishing, silica particles to approach a polycrystalline silicon film, so that mechanical force can be effectively applied to the polycrystalline silicon film by the silica particles.

Silica particles are preferably colloidal silica. Examples of a method for producing colloidal silica include a soda silicate method and a sol-gel method, and colloidal silica produced by any of these methods is suitably used as the silica particles of the present invention. However, from the viewpoint of reducing metal impurities, colloidal silica produced by a sol-gel method that enables high-purity production is preferred.

Furthermore, silica particles may be surface-modified, as long as the silanol group density satisfies the above ranges. For example, silica particles may also be colloidal silica with organic acid immobilized thereto. Such immobilization of an organic acid to the surface of the colloidal silica contained in the polishing composition is performed by, for example, chemical bonding of functional groups of the organic acid with the surface of the colloidal silica. Simple coexistence of colloidal silica and the organic acid cannot achieve the immobilization of the organic acid to the colloidal silica. If sulfonic acid that is a type of such organic acid is immobilized to the colloidal silica, for example, this can be achieved by a method described in “Sulfonic acid-functionalized silica through quantitative oxidation of thiol groups”, Chem. Commun. 246-247 (2003). Specifically, after coupling of a silane coupling agent having thiol groups such as 3-mercaptopropyltrimethoxysilane with the colloidal silica, the thiol groups are oxidized with hydrogen peroxide, and thus the colloidal silica with the sulfonic acid immobilized to the surface thereof can be obtained. Alternatively, if carboxylic acid is immobilized to colloidal silica, for example, this can be performed by a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, after coupling of a silane coupling agent containing photolabile 2-nitrobenzyl ester with the colloidal silica, the colloidal silica is irradiated with light, and thus the colloidal silica with carboxylic acid immobilized to the surface thereof can be obtained.

In the polishing composition of the present invention, examples of abrasive grains may include abrasive grains other than silica particles which have the number of silanol groups of higher than 0 group/nm² and 4 groups/nm² or less (hereinafter, other abrasive grains). Types of other abrasive grains contained in the polishing composition of the present invention are not particularly limited, and examples thereof include oxides such as silica other than silica particles which have the number of silanol groups of higher than 0 group/nm² and 4 groups/nm² or less, alumina, zirconia, and titania. Other abrasive grains can be used singly or in combinations of two or more thereof. As other abrasive grains, a commercial product thereof or a synthetic product thereof may also be used.

Note that in the above description, when grains/particles are referred to as “abrasive grains”, specifically, unless otherwise specified as “silica particles”, such grains/particles indicate silica particles and other abrasive grains having the number of silanol groups of higher than 0 group/nm² and 4 groups/nm² or less without particular differentiation.

In the polishing composition of the present invention, silica particles preferably have a negative zeta potential. Here, the term “zeta (ζ) potential” refers to the potential difference generated at the interface between a solid and a liquid that are in contact with each other, when the two are in relative motion. In the polishing composition of the present invention, abrasive grains are negatively charged, so as to be able to improve the speed of polishing an object to be polished. The zeta potential of silica particles is preferably −80 mV or more and −10 mV or less, more preferably −70 mV or more and −15 mV or less, further preferably −65 mV or more and −20 mV or less, and particularly preferably −60 mV or more and −25 mV or less. Silica particles have a zeta potential within such a range, so that desired effects of the present invention can be exhibited efficiently.

The zeta potential of abrasive grains in the polishing composition is calculated by subjecting the polishing composition to measurement by a laser Doppler method (electrophoretic Light Scattering: ELS) using ELS-Z2 (manufactured by Otsuka Electronics Co., Ltd.) and a flow cell at a measurement temperature of 25° C., for analysis of the obtained data using Smoluchowski's formula.

The lower limit of the average primary particle size of silica particles is preferably 5 nm or more, more preferably 7 nm or more, further preferably 10 nm or more, particularly preferably 15 nm or more, and most preferably 20 nm or more. The upper limit of the average primary particle size of silica particles is preferably 300 nm or less, more preferably 250 nm or less, further preferably 200 nm or less, particularly preferably 180 nm or less, and most preferably 150 nm or less. With the limits within such ranges, the desired effects of the present invention can be efficiently exhibited.

The value of the average primary particle size of abrasive grains can be calculated based on the specific surface area measured using the BET method.

The lower limit of the average secondary particle size of silica particles is preferably 10 nm or more, more preferably 20 nm or more, further preferably 30 nm or more, particularly preferably 40 nm or more, and most preferably 50 nm or more. Further, the upper limit of the average secondary particle size of silica particles is preferably 200 nm or less, more preferably 180 nm or less, further preferably 150 nm or less, particularly preferably 100 nm or less, and most preferably 80 nm or less. Specifically, the average secondary particle size of silica particles is preferably 10 nm or more and 200 nm or less, more preferably 20 nm or more and 180 nm or less, further preferably 30 nm or more and 150 nm or less, particularly preferably 40 nm or more and 100 nm or less, and most preferably 10 nm or more and 250 nm or less. With the limits within such ranges, the desired effects of the present invention can be efficiently exhibited.

Note that the average secondary particle size of abrasive grains can be measured by, for example, a dynamic light scattering method represented by a laser diffraction/scattering method. Specifically, the average secondary particle size of abrasive grains corresponds to the particle diameter D50 when the accumulated mass of particles from the particulate side reaches 50% of the total mass of particles in the particle size distribution of abrasive grains found by the laser diffraction/scattering method.

The average degree of association of abrasive grains is preferably 4.0 or less, more preferably 3.0 or less, and further preferably 2.5 or less. As the average degree of association of abrasive grains decreases, the chances of forming defects on the surface of an object to be polished can be even more reduced. Further, the average degree of association of abrasive grains is preferably 1.5 or more, and more preferably 1.8 or more. There is an advantage that as the average degree of association of abrasive grains increases, the speed of polishing with the use of the polishing composition is improved. Note that the average degree of association of abrasive grains can be obtained by dividing the value of the average secondary particle size of abrasive grains by the value of the average primary particle size.

The sizes of abrasive grains (average primary particle size, average secondary particle size etc.) can be appropriately controlled by selection or the like of a method for producing abrasive grains.

The lower limit of the content (concentration) of abrasive grains in the polishing composition according to an embodiment of the present invention is preferably 0.2 mass % or more, more preferably 0.3 mass % or more, and further preferably 0.5 mass % or more with respect to the polishing composition. Moreover, in the polishing composition of the present invention, the upper limit of the content of abrasive grains is preferably 20 mass % or less, more preferably 15 mass % or less, further preferably 10 mass % or less, and even more preferably 5 mass % or less with respect to the polishing composition. With the limits within such ranges, the polishing speed can be even more improved. Note that when the polishing composition contains 2 or more types of abrasive grains, the content of the abrasive grains means the total amount thereof.

[Alkaline Compound]

The polishing composition of the present invention contains an alkaline compound in an embodiment. The alkaline compound has an action of adjusting pH and an action of adjusting electrical conductivity in the polishing composition of the present invention. Examples of the alkaline compound include: alkali metal hydroxides such as sodium hydroxide and potassium hydroxide; carbonates such as sodium carbonate and potassium carbonate; amines such as ethylenediamine, diglycolamine, piperazine, and aminoethylpiperazine; and ammonia. The alkaline compounds can be used independently or 2 or more types thereof can be mixed and then used. Through the use of these alkaline compounds, pH can be adjusted within the alkaline range where polycrystalline silicon and silicon oxide contained in an object to be polished can be easily dissolved. Moreover, through the use of these alkaline compounds, the electrical conductivity of the polishing composition can be adjusted within a range such that an electric double layer formed at the interface between abrasive grains and a wafer (polycrystalline silicon film or silicon oxide film) is compressed, so as to reduce the size of a region where electrostatic repulsion begins to occur between the two. This allows abrasive grains to easily approach the wafer, improving the polishing speed. Alkaline compounds are almost never adsorbed to the surface of abrasive grains or the surface of an object to be polished during polishing, and most alkaline compounds are dissolved in a dispersing medium, so that the alkaline compounds will almost never inhibit or never inhibit the polishing of the polycrystalline silicon film and the silicon oxide film. Therefore, the polishing composition according to the present invention containing alkaline compounds can realize efficient polishing and can efficiently exhibit the desired effects of the present invention.

In the present invention, from the view point of pH adjustment and adjustment of electrical conductivity, potassium hydroxide is preferably used as an alkaline compound. Further, from the view point of electrical conductivity, potassium carbonate is preferably contained as an alkaline compound. From the view point of polishing speed, diglycolamine, aminoethylpiperazine, and ammonia are preferably contained as alkaline compounds. Accordingly, in a preferred embodiment, as alkaline compounds, one or more selected from the group consisting of potassium carbonate, diglycolamine, aminoethylpiperazine and ammonia are preferably contained.

Further, the polishing composition of the present invention contains, as the alkaline compounds, one or more selected from the group consisting of diglycolamine, aminoethylpiperazine and ammonia, so that the speeds of polishing a polycrystalline silicon film and a silicon oxide film can be even more improved.

In an embodiment, the alkaline compound(s) is one or more selected from the group consisting of potassium hydroxide, potassium carbonate, diglycolamine, aminoethylpiperazine and ammonia. Further, in an embodiment, the alkaline compounds include potassium hydroxide and one or more selected from the group consisting of potassium carbonate, diglycolamine, aminoethylpiperazine and ammonia. In an embodiment, the alkaline compounds include potassium hydroxide and one or more selected from the group consisting of aminoethylpiperazine and diglycolamine. The polishing composition contains such alkaline compounds, so that the desired effects of the present invention can be efficiently exhibited. Further, in an embodiment, in the polishing composition of the present invention, the alkaline compounds are substantially composed of potassium hydroxide and one or more selected from the group consisting of potassium carbonate, diglycolamine, aminoethylpiperazine and ammonia. Accordingly, the desired effects of the present invention can be further efficiently exhibited.

The content (concentration) of the alkaline compound(s) is not particularly limited, and can be adequately adjusted so that the polishing composition has desired pH and electrical conductivity. For example, the content of the alkaline compound(s) is preferably 0.01 mass % or more, more preferably 0.05 mass % or more, and further preferably 0.15 mass % or more with respect to the total mass of the polishing composition. Further, the upper limit of the content of the alkaline compound(s) is preferably 10 mass % or less, more preferably 5 mass % or less, further preferably 2 mass % or less, even more preferably 1 mass %, and most preferably 0.5 mass % or less with respect to the total mass of the polishing composition. Note that when the polishing composition contains two or more alkaline compounds, the content of the alkaline compounds is intended to be the total amount thereof. In an embodiment, when potassium hydroxide and one or more selected from the group consisting of potassium carbonate, diglycolamine, aminoethylpiperazine and ammonia are used as the alkaline compounds, the content of potassium carbonate, diglycolamine, aminoethylpiperazine or ammonia (when the two or more thereof are used, the total amount thereof) is preferably 0.01 mass % or more and 1 mass % or less, more preferably 0.02 mass % or more and 1 mass % or less, and further preferably 0.05 mass % or more and 0.5 mass % or less with respect to the total mass of the polishing composition.

[Electrical Conductivity]

The polishing composition of the present invention has electrical conductivity of 0.5 mS/cm or more and 10 mS/cm or less. The polishing composition of the present invention has electrical conductivity of, in an embodiment, 3 mS/cm or more and 8 mS/cm or less. When the polishing composition has electrical conductivity of less than 0.5 mS/cm, an electric double layer formed at the interface between abrasive grains and a wafer (polycrystalline silicon film or silicon oxide film) increases in size, and thus the region where electrostatic repulsion occurs is increased. As a result, total electrostatic repulsion increases, making abrasive grains difficult to approach the wafer, and decreasing the polishing speed. On the other hand, when the polishing composition has electrical conductivity of higher than 10 mS/cm, electrostatic repulsion among abrasive grains decreases and abrasive grains aggregate, causing a problem in storage stability.

The lower limit of electrical conductivity of the polishing composition is preferably 1 mS/cm or more, more preferably 2 mS/cm or more, further preferably 3 mS/cm or more, particularly preferably 4 mS/cm or more, and most preferably 5 mS/cm or more. Further, the upper limit of electrical conductivity of the polishing composition of the present invention is preferably 9 mS/cm or less, more preferably 8 mS/cm or less, further preferably 7.5 mS/cm or less, particularly preferably 7 mS/cm or less, and most preferably 6 mS/cm or less. Specifically, the polishing composition of the present invention has electrical conductivity of preferably 1 mS/cm or more and 9 mS/cm or less, more preferably 2 mS/cm or more and 8 mS/cm or less, further preferably 3 mS/cm or more and 7.5 mS/cm or less, particularly preferably 4 mS/cm or more and 7 mS/cm or less, and most preferably 5 mS/cm or more and 6 mS/cm or less. The polishing composition has electrical conductivity within the above range, so that the desired effects of the present invention can be efficiently exhibited. Note that the electrical conductivity of the polishing composition is a value measured by a desktop electrical conductivity sensor (manufactured by HORIBA, Ltd., Model: DS-71).

[pH and pH Adjusting Agent]

The polishing composition of the present invention has a pH of 10 or more and 12 or less. When the polishing composition has a pH of less than 10, the speed of polishing an object to be polished, a polycrystalline silicon film and a silicon oxide film, cannot be improved, and the desired effects of the present invention are not exhibited. The pH of the polishing composition of the present invention may be 10 or more, is preferably 10.5 or more, more preferably 10.9 or more, further preferably 11 or more, even more preferably higher than 11, particularly preferably 11.1 or more, and most preferably 11.2 or more. When the polishing composition has a pH of higher than 12, objects to be polished, a polycrystalline silicon film and a silicon oxide film, are excessively polished, and the selection ratio of the polishing speed of a polycrystalline silicon film is decreased. The pH of the polishing composition of the present invention may be 12 or less, is preferably less than 12, more preferably 11.9 or less, further preferably less than 11.9, even more preferably 11.8 or less, particularly preferably 11.7 or less, and most preferably 11.6 or less.

Note that the pH of the polishing composition can be measured with a pH meter, for example. Specifically, after 3-point calibration using a pH meter (e.g., manufactured by HORIBA, Ltd., model: LAQUA) or the like, and a standard buffer solution (phthalate pH buffer solution pH: 4.01 (25° C.), neutral phosphate pH buffer solution pH: 6.86 (25° C.), carbonate pH buffer solution pH: 10.01 (25° C.)), a glass electrode is placed in the polishing composition, and then after two or more minutes, the stabilized value is measured, and thus the pH of the polishing composition can be measured.

The polishing composition of the present invention contains abrasive grains, an alkaline compound, and a dispersing medium as essential components. When it is difficult to obtain desired pH with these components alone, a pH adjusting agent may be added to adjust pH as long as the effects of the present invention are not inhibited.

The pH adjusting agent may be a base, an inorganic acid, or an organic acid other than the above alkaline compounds, and these may be used singly or in combinations of two or more thereof.

Specific examples of a base that can be used as a pH adjusting agent include compounds other than the above alkaline compounds, such as quaternary ammonium hydroxide or a salt thereof. Specific examples of such a salt include sulfate and acetate.

Specific examples of an inorganic acid that can be used as a pH adjusting agent include hydrochloric acid, sulfuric acid, nitric acid, hydrofluoric acid, boric acid, carbonic acid, hypophosphorous acid, phosphorous acid and phosphoric acid. Particularly preferred examples thereof are hydrochloric acid, sulfuric acid, nitric acid, or phosphoric acid.

Specific examples of an organic acid that can be used as a pH adjusting agent include formic acid, acetic acid, propionic acid, butyric acid, valeric acid, 2-methyl butyric acid, n-hexanoic acid, 3,3-dimethylbutyric acid, 2-ethylbutyric acid, 4-Methylpentanoic Acid, n-heptanoic acid, 2-methylhexanoic acid, n-octanoic acid, 2-ethyl hexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofuroic acid, methoxyacetic acid, methoxyphenylacetic acid and phenoxyacetic acid. Organic sulfuric acid such as methansulfonic acid, ethanesulfonic acid and isethionic acid may also be used. Particularly preferred examples thereof are dicarboxylic acid such as malonic acid, succinic acid, glutaric acid, adipic acid, pimelic acid, maleic acid, phthalic acid, malic acid and tartaric acid, as well as tricarboxylic acid such as citric acid.

Instead of an inorganic acid or an organic acid, or with a combination with an inorganic acid or an organic acid, a salt such as an alkali metal salt of an inorganic acid or an organic acid may also be used as a pH adjusting agent. In the case of a combination of a weak acid and a strong base, that of a strong acid and a weak base, or that of a weak acid and a weak base, the pH buffering action can be expected.

The amount of a pH adjusting agent added is not particularly limited, and may be appropriately adjusted in such a manner that the polishing composition has a desired pH.

[Dispersing Medium]

The polishing composition of the present invention contains a dispersing medium for dispersing each component. Examples of the dispersing medium can include water, alcohols such as methanol, ethanol, and ethylene glycol, ketones such as acetone, and mixtures thereof. Of these, water is preferred as a dispersing medium. Specifically, according to a preferred embodiment of the present invention, the dispersing medium includes water. According to a more preferred embodiment of the present invention, the dispersing medium is substantially composed of water. Note that the above “substantially” is intended to mean that a dispersing medium other than water can be contained as long as the purpose and the effects of the present invention can be achieved. More specifically, the dispersing medium includes preferably 90 mass % or more and 100 mass % or less of water and 0 mass % or more and 10 mass % or less of a dispersing medium other than water, and more preferably 99 mass % or more and 100 mass % or less of water and 0 mass % or more and 1 mass % or less of a dispersing medium other than water. Most preferably, the dispersing medium is water.

Water containing impurities in an amount as low as possible is preferred as the dispersing medium from the viewpoint of not inhibiting the action of components contained in the polishing composition. Specifically, pure water or ultra-pure water, which is obtained by removing foreign matters through a filter after removal of impurity ions using an ion exchange resin, or distilled water is more preferred.

[Other Components]

The polishing composition of the present invention may further contain as necessary a known additive that can be used for the polishing composition, such as a complexing agent, an antiseptic agent, and an antifungal agent, as long as the effects of the present invention are not significantly inhibited. However, according to an embodiment of the present invention, the polishing composition substantially contains no oxidizing agent. According to such an embodiment, even when an object to be polished containing a polycrystalline silicon film and a silicon oxide film (preferably TEOS film) is polished, the polycrystalline silicon film and the silicon oxide film can be polished at high polishing speeds, and the selection ratio of the polishing speed of a polycrystalline silicon film (the ratio of the polishing speed of the polycrystalline silicon film to the polishing speed of the silicon oxide film) is high. Note that the expression “substantially contains no (oxidizing agent)” is intended to include a concept of containing no such additive in the polishing composition, and a case of containing 0.1 mass % or less of such additive in the polishing composition. In the polishing composition of the present invention, the total content of abrasive grains, an alkaline compound, and a dispersing medium is preferably higher than 99 mass % (upper limit: 100 mass %) with respect to the total mass (100 mass %) of the polishing composition. The polishing composition of the present invention may also be composed of abrasive grains, an alkaline compound, and a dispersing medium, and an antifungal agent (the above total content=100 mass %). More preferably, the polishing composition is composed of abrasive grains, an alkaline compound, and a dispersing medium (the above total content=100 mass %).

[Method for Producing Polishing Composition]

A method for producing the polishing composition of the present invention is not particularly limited. For example, the polishing composition can be obtained by mixing and stirring abrasive grains, and other components as necessary in a dispersing medium (e.g., water). Each component is as described in detail above.

Temperature at which each component is mixed is not particularly limited, and the temperature is preferably 10° C. or higher and 40° C. or lower, and the mixture may also be heated in order to increase the rate of dissolution. Further the time for mixing is not particularly limited, as long as the mixture can be mixed uniformly.

[Polishing Method and Method for Producing Semiconductor Substrate]

As described above, the polishing composition of the present invention is suitably used for polishing an object to be polished containing a polycrystalline silicon film and a silicon oxide film. Therefore, the present invention provides a method for polishing an object to be polished containing a polycrystalline silicon film and a silicon oxide film using the polishing composition of the present invention. Specifically, the present invention encompasses a polishing method including a step of polishing an object to be polished containing a polycrystalline silicon film and a silicon oxide film using the polishing composition of the present invention. Further, the present invention provides a method for producing a semiconductor substrate including a step of polishing a semiconductor substrate containing a polycrystalline silicon film and a silicon oxide film by the above polishing method.

As a polishing apparatus, it is possible to use a general polishing apparatus provided with a holder for holding a substrate or the like having an object to be polished, a motor or the like having a changeable rotation number, and a platen to which a polishing pad (polishing cloth) can be attached.

As the polishing pad, a general nonwoven fabric, polyurethane, a porous fluororesin, or the like can be used without any particular limitation. The polishing pad is preferably grooved such that a polishing liquid can be stored therein.

Regarding polishing conditions, for example, the rotational speed of a platen is preferably 10 rpm (0.17 s⁻¹) or more and 500 rpm (8.3 s⁻¹) or less. The pressure (polishing pressure) applied to a substrate having an object to be polished is preferably 0.5 psi (3.4 kPa) or more and 10 psi (68.9 kPa) or less. A method for supplying the polishing composition to a polishing pad is also not particularly limited. For example, a method for continuously supplying a polishing composition using a pump or the like is employed. The amount to be supplied is not limited, but a surface of the polishing pad is preferably covered all the time with the polishing composition of the present invention.

After completion of polishing, the substrate is cleaned in running water, water droplets adhered onto the substrate are removed using a spin dryer or the like for drying, and thus the substrate having a polycrystalline silicon film and a silicon oxide film is obtained.

The polishing composition of the present invention may be of a one-component type or a multi-component type including a two-component type. Further, the polishing composition of the present invention may be prepared by, for example, diluting 10 or more times a stock solution of the polishing composition using a diluent such as water.

[Method for Polishing Polycrystalline Silicon Film and Silicon Oxide Film at High Polishing Speeds while Increasing the Selection Ratio of the Polishing Speed of Polycrystalline Silicon Film]

According to the present invention, a method, by which a polycrystalline silicon film and a silicon oxide film can be polished at high polishing speeds, and the selection ratio of the polishing speed of polycrystalline silicon can be increased, is also provided. The above descriptions are applied as specific descriptions for the polishing composition.

[Polishing Speed]

In the present invention, the speed (polishing speed) of polishing a polycrystalline silicon film is preferably 2000 Å/min or more and 7000 Å/min or less, more preferably 2200 Å/min or more and 6800 Å/min or less, further preferably 2500 Å/min or more and 6500 Å/min or less, and particularly preferably 3000 Å/min or more and 6000 Å/min or less. The speed of polishing a silicon oxide film (TEOS film) is preferably 35 Å/min or more and 500 Å/min or less, more preferably 50 Å/min or more and 300 Å/min or less, further preferably 80 Å/min or more and 250 Å/min or less, and particularly preferably 100 Å/min or more and 200 Å/min or less. Note that 1 Å=0.1 nm.

[Selection Ratio]

When the polishing speed (Å/min) of a polycrystalline silicon film (poly-Si) is divided by the polishing speed (Å/min) of a silicon oxide film (TEOS) to give a selection ratio, in the present invention, the selection ratio (poly-Si/TEOS) is preferably 10 or more and 50 or less, more preferably 11 or more and 45 or less, and further preferably 15 or more and 40 or less.

The embodiments of the present invention are described in detail above, but are explanatory and illustrative only, and are not limited. The scope of the present invention should be obviously construed on the basis of the attached claims.

The present invention encompasses the following aspects and embodiments.

1. A polishing composition, containing abrasive grains, an alkaline compound, and a dispersing medium, wherein

the abrasive grains contain silica particles having a silanol group density of higher than 0 group/nm² and 4 groups/nm² or less,
electrical conductivity is 0.5 mS/cm or more and 10 mS/cm or less, and
pH is 10 or more and 12 or less.

2. The polishing composition according to 1 above, wherein the alkaline compound is one or more selected from the group consisting of potassium hydroxide, potassium carbonate, diglycolamine, aminoethylpiperazine and ammonia.

3. The polishing composition according to 1 or 2 above, wherein the silica particles have a silanol group density of higher than 0 group/nm² and 2 groups/nm² or less.

4. The polishing composition according to any one of 1 to 3 above, containing as the alkaline compounds, potassium hydroxide, and one or more selected from the group consisting of potassium carbonate, diglycolamine, aminoethylpiperazine and ammonia.

5. The polishing composition according to any one of 1 to 4 above, wherein the electrical conductivity is 3 mS/cm or more and 8 mS/cm or less.

6. The polishing composition according to any one of 1 to 5 above, containing as the alkaline compounds, potassium hydroxide, and

one or more selected from the group consisting of diglycolamine and aminoethylpiperazine.

7. The polishing composition according to any one of 1 to 6 above, wherein the pH is higher than 11.

8. The polishing composition according to any one of 1 to 7 above, containing substantially no oxidizing agent.

9. The polishing composition according to any one of 1 to 8 above, which is used for polishing an object to be polished containing a polycrystalline silicon film and a silicon oxide film.

10. A polishing method, comprising a step of polishing an object to be polished containing a polycrystalline silicon film and a silicon oxide film using the polishing composition according to any one of 1 to 9 above.

11. A method for producing a semiconductor substrate, including a step of polishing a semiconductor substrate including a polycrystalline silicon film and a silicon oxide film by the polishing method according to 10 above.

### EXAMPLES

The present invention will be described in more detail using the following Examples and Comparative Examples, but the technical scope of the present invention is not limited to only the following Examples. Note that unless otherwise specified, “%” and “part(s)” refer to “mass %” and “parts by mass”, respectively. Further, in the following Examples, unless otherwise specified, operation was performed under conditions of room temperature (20° C. to 25° C.)/relative humidity of 40% RH to 50% RH.

[Preparation of Abrasive Grains]

(Preparation of Silica Particles)

As silica particles, silica particles having silanol group densities described in Table 1 were prepared. Specifically, silica particles were, for example, sintered by maintaining silica under an environment at 120° C. to 200° C. for 30 minutes or longer, so as to adjust the number of silanol groups on the surface of silica particles to be a desired numerical value such as a value of higher than 0 group/nm² and 4 groups/nm² or less.
Silica particles a: silanol group density of 1.6 groups/nm², average primary particle size: 30 nm, average secondary particle size: 70 nm, average degree of association: 2.3
Silica particles b: silanol group density of 3.5 groups/nm², average primary particle size: 30 nm, average secondary particle size: 70 nm, average degree of association: 2.3
Silica particles c: silanol group density of 5.7 groups/nm², average primary particle size: 35 nm, average secondary particle size: 70 nm, average degree of association: 2
   Note that the silanol group density (unit: group/nm²) of silica particles was calculated by the following method after measurement and calculation of each parameter by the following measurement method and calculation method.

[Method for Calculating Silanol Group Density]

The silanol group density of silica particles was calculated by the Sears method using neutralization titration described in G. W. Sears, Analytical Chemistry, vol. 28, No. 12, 1956, 1982 to 1983.

More specifically, the silanol group density of silica particles was calculated by the following formula 1, after titration of each type of silica particles as a measurement sample by the above method.

ρ=(c×V×N_{A}×10⁻²¹)/(C×S) Formula 1

In the above Formula 1,

ρ denotes silanol group density (number of groups/nm²);

c denotes the concentration (mol/L) of a sodium hydroxide solution used for titration;

V denotes the volume (L) of the sodium hydroxide solution required to increase pH from 4.0 to 9.0;

N_{A} denotes Avogadro's constant (number of particles/mol); and

S denotes BET specific surface area (nm/g) of silica particles.

[Particle Size of Silica Particles]

The average primary particle size of abrasive grains (silica particles) was calculated from the specific surface area of abrasive grains as measured by the BET method using “Flow SorbII 2300” (manufactured by Micromeritics) and the density of abrasive grains. Further, the average secondary particle size of abrasive grains (silica particles) was measured by a dynamic light scattering particle size⋅particle size distribution apparatus UPA-UTI151 (manufactured by NIKKISO CO., LTD.).

[Preparation of Polishing Composition]

### Example 1

As abrasive grains, the above obtained silica particles “a” (silanol group density of 1.6 groups/nm², average primary particle size: 30 nm, average secondary particle size: 70 nm, average degree of association: 2.3) and as an alkaline compound, aminoethylpiperazine were each added to a dispersing medium, pure water, at room temperature (25° C.) in such a manner that the final concentrations thereof were 2 mass % and 0.1 mass %, respectively, thereby obtaining a mixed solution.

Subsequently, to adjust pH, potassium hydroxide was added as an alkaline compound to the mixed solution in such a manner that the pH was 11.3, and then the solution was stirred and mixed at room temperature (25° C.) for 30 minutes, thereby preparing a polishing composition. The pH of the polishing composition (liquid temperature: 25° C.) was confirmed using a pH meter (manufactured by HORIBA, Ltd. Model: LAQUA).

[Particle Size of Silica Particles]

The particle sizes (average primary particle size, average secondary particle size) of the abrasive grains in the thus obtained polishing composition were the same as those of powdery abrasive grains. In addition, the method for measuring particle sizes is the same as that described above.

[Zeta Potential]

The zeta potential of abrasive grains (silica particles) in the polishing composition was measured using a zeta potential analyzer (manufactured by Otsuka Electronics Co., Ltd., Apparatus name “ELS-Z2”).

[Electrical Conductivity]

The electrical conductivity (unit: mS/cm) of the polishing composition (liquid temperature: 25° C.) was measured using a desktop-type electrical conductivity sensor (manufactured by HORIBA, Ltd., Model: DS-71).

### Examples 2 to 9, Comparative Examples 1 to 3

The polishing compositions of Examples 2 to 9 and Comparative Examples 1 to 3 were each prepared in the same manner as in Example 1, except for changing the types of silica particles and the types and the contents of alkaline compounds (pH and electrical conductivity) as described in Table 1 below. Note that in Table 1 below, abrasive grains having a silanol group density of 1.6 group/nm² were silica particles a, abrasive grains having a silanol group density of 3.5 groups/nm² were silica particles b, and abrasive grains having a silanol group density of 5.7 groups/nm² were silica particles c. Further in Table 1 below, those denoted with “-” indicate that relevant agents were not contained. The pH and the electrical conductivity of each of the obtained polishing compositions, the average secondary particle size and the zeta potential of abrasive grains (silica particles) in each polishing composition are described in Table 1 below. Note that the particle sizes (average primary particle size, average secondary particle size) of abrasive grains in each of the obtained polishing compositions were similar to the particle sizes of powdery abrasive grains.

In Table 1, “particle size” of silica particles indicates the average secondary particle size, “AEP” in the column of alkaline compound indicates aminoethylpiperazine, “DGA” indicates diglycolamine, and “EC” indicates electrical conductivity. “Poly-Si” in the column of polishing speed indicates a polycrystalline silicon film. “Poly-Si/TEOS” in the column of selection ratio indicates the selection ratio of a polycrystalline silicon film with respect to a TEOS film, which is calculated by dividing the polishing speed of the polycrystalline silicon film by the polishing speed of the TEOS film.

[Evaluation of Polishing Speed]

The polishing speed when each of the following objects to be polished were polished using each of the above-obtained polishing compositions under the following polishing conditions was measured.

(Polishing Apparatus and Polishing Conditions)

Polishing apparatus: manufactured by Engis Japan Corporation, wrapping machine EJ-380IN-CH

Polishing pad: manufactured by NITTA DuPont Incorporated, hard polyurethane pad IC1010

Polishing pressure: 3.0 psi (1 psi=6894.76 Pa) Rotation number of platen: 60 rpm

Rotation number of head (carrier): 60 rpm Supply of polishing composition: flowing (discarded after single use)

Supply amount of polishing composition: 100 mL/minute

Polishing time: 60 seconds

(Object to be Polished)

As an object to be polished, a 300-mm blanket wafer having a polycrystalline silicon film with a thickness of 5000 Å formed on the surface was prepared. Further as an object to be polished, a silicon wafer (300 mm, blanket wafer, manufactured by ADVANTEC CO., LTD.) having a TEOS film with a thickness of 500 Å formed on the surface was prepared. Subsequently, the wafer was cut into 30 mm×30 mm chips to prepare coupons as test specimens, and then a polishing test was conducted. Objects to be polished, which were used for the test, will be described in detail as follows.

(Polishing Speed)

Polishing speed (Removal Rate; RR) was calculated by the following formula.

$$Polishing speed [ Å / min ] = \frac{\begin{matrix}Film thickness \\ before polishing [ Å ]\end{matrix} - \begin{matrix}Film thickness \\ after polishing [ Å ]\end{matrix}}{Polishing time [ min ]} \qquad [ Formula 1 ]$$

Film thickness was determined using a light interference type film thickness measurement apparatus (manufactured by Dainippon Screen Mfg. Co., Ltd., Model: Lambda Ace VM-2030), and then the difference between the film thickness before polishing and the same after polishing was divided by polishing time for evaluation of the polishing speed.

The results of evaluating the polishing speed for the polycrystalline silicon film and the same for the TEOS film are shown in Table 1 below.

TABLE 1

| | Abrasive grains | | | | Alkaline compound | | | | | | | |
|---|---|---|---|---|---|---|---|---|---|---|---|---|
| | | | | Silanol | | | Concentra- | | | | | |
| | | | | group | | | tion of | Physical | | Polishing | | Selection |
| | Concentra- | Particle | Zeta | density | | | compo- | property | | speed | | ratio |
| | tion | size | potential | [number of | Compo- | Compo- | nent 2 | | EC | poly-Si | TEOS | poly- |
| | [mass %] | [nm] | [mV] | groups/nm²] | nent 1 | nent 2 | [mass %] | pH | [mS/cm] | [Å/min] | [Å/min] | Si/TEOS |
| Example 1 | 2 | 70 | −52 | 1.6 | KOH | AEP | 0.1 | 11.3 | 5.6 | 4262 | 157 | 27 |
| Example 2 | 2 | 70 | −52 | 1.6 | KOH | DGA | 0.1 | 11.3 | 5.6 | 4121 | 148 | 28 |
| Example 3 | 2 | 70 | −52 | 1.6 | KOH | NH₃ | 0.1 | 11.3 | 5.6 | 3570 | 144 | 25 |
| Example 4 | 2 | 70 | −47 | 1.6 | KOH | K₂CO₃ | 0.3 | 10.4 | 5.6 | 2212 | 165 | 13 |
| Example 5 | 2 | 70 | −50 | 1.6 | KOH | — | — | 10.8 | 1.0 | 2276 | 100 | 23 |
| Example 6 | 2 | 70 | −51 | 1.6 | KOH | — | — | 11.0 | 2.5 | 2311 | 102 | 23 |
| Example 7 | 2 | 70 | −53 | 1.6 | KOH | — | — | 11.5 | 7.0 | 2265 | 187 | 12 |
| Example 8 | 2 | 70 | −51 | 3.5 | KOH | — | — | 11.0 | 2.5 | 2287 | 121 | 19 |
| Example 9 | 2 | 70 | −51 | 3.5 | KOH | NH₃ | 0.1 | 11.0 | 2.5 | 2890 | 131 | 22 |
| Comparative | 2 | 70 | −46 | 1.6 | KOH | — | — | 10.0 | 0.2 | 1780 | 25 | 71 |
| Example 1 | | | | | | | | | | | | |
| Comparative | 2 | 70 | −47 | 5.7 | KOH | — | — | 10.5 | 1.0 | 1956 | 31 | 63 |
| Example 2 | | | | | | | | | | | | |
| Comparative | 2 | 70 | −57 | 1.6 | KOH | — | — | 12.5 | 15.0 | 2400 | 270 | 9 |
| Example 3 | | | | | | | | | | | | |

As shown in Table 1, when the polishing compositions of Examples 1 to 9 were used, the polishing speed for the polycrystalline silicon film exceeded 2000 Å/min and the polishing speed for the TEOS film was 100 Å/min or more, revealing that the polishing compositions of Examples 1 to 9 are capable of polishing at speeds higher than those in the case of the polishing compositions of Comparative Examples 1 to 3. Moreover, when the polishing compositions of Examples 1 to 9 were used, the selection ratio of the polishing speed for the polycrystalline silicon film was 10 or more and 50 or less, revealing that the polishing compositions of Examples 1 to 9 are capable of polishing the polycrystalline silicon film and the TEOS film at high polishing speeds, and are capable of polishing the polycrystalline silicon film with a high selection ratio.

As is understood from the above results, a polishing composition having a pH and electrical conductivity within specific ranges and containing silica particles having a specific silanol group density is capable of polishing a polycrystalline silicon film and a TEOS film at high polishing speeds and polishing the polycrystalline silicon film with a high selection ratio.

The present application is based on the Japanese patent application No. 2021-049533 filed on Mar. 24, 2021, and the disclosed content thereof is incorporated herein by reference in their entirety.

1. A polishing composition, comprising abrasive grains, an alkaline compound, and a dispersing medium, wherein the abrasive grains contain silica particles having a silanol group density of higher than 0 group/nm² and 4 groups/nm² or less,
electrical conductivity is 0.5 mS/cm or more and 10 mS/cm or less, and
pH is 10 or more and 12 or less.

2. The polishing composition according to claim 1, wherein the alkaline compound is one or more selected from the group consisting of potassium hydroxide, potassium carbonate, diglycolamine, aminoethylpiperazine and ammonia.

3. The polishing composition according to claim 1, wherein the silica particles have a silanol group density of higher than 0 group/nm² and 2 groups/nm² or less.

4. The polishing composition according to claim 1, comprising as the alkaline compounds,
potassium hydroxide, and
one or more selected from the group consisting of potassium carbonate, diglycolamine, aminoethylpiperazine and ammonia.

5. The polishing composition according to claim 1, wherein the electrical conductivity is 3 mS/cm or more and 8 mS/cm or less.

6. The polishing composition according to claim 1, comprising as the alkaline compounds,
potassium hydroxide, and
one or more selected from the group consisting of diglycolamine and aminoethylpiperazine.

7. The polishing composition according to claim 1, wherein the pH is higher than 11.

8. The polishing composition according to claim 1, comprising substantially no oxidizing agent.

9. The polishing composition according to claim 1, which is used for polishing an object to be polished containing a polycrystalline silicon film and a silicon oxide film.

10. A polishing method, comprising a step of polishing an object to be polished containing a polycrystalline silicon film and a silicon oxide film using the polishing composition according to claim 1.

11. A method for producing a semiconductor substrate, comprising a step of polishing a semiconductor substrate including a polycrystalline silicon film and a silicon oxide film by the polishing method according to claim 10.
